(19) United States
(12) Patent Application Publication
(10) Pub. No.: US 2023/0307549 A1
(43) Pub. Date: Sep. 28, 2023

(54) SPUTTERING TARGET MATERIAL AND OXIDE SEMICONDUCTOR

(71) Applicant: Mitsui Mining & Smelting Co., Ltd., Tokyo (JP)

(72) Inventors: Kyosuke TERAMURA, Omuta (JP); Ryo SHIRANITA, Omuta (JP); Shigeki TOKUCHI, Ageo (JP)

(21) Appl. No.: 18/014,432

(22) PCT Filed: Aug. 2, 2021
(86) PCT No.: PCT/JP2021/028640

§ 371 Date: Jan. 4, 2023

(30) Foreign Application Priority Data
Aug. 5, 2020 (JP) 2020-133080

(51) Int. Cl. H01L 29/786; C23C 14/34; C23C 14/08; H01L 21/02

(52) U.S. Cl. CPC H01L 29/78693; C23C 14/082; C23C 14/083; C23C 14/086; C23C 14/3407; H01L 21/02565; H01L 21/02592; H01L 21/02631

(57) ABSTRACT

A sputtering target material comprises an oxide including elemental indium (In), elemental zinc (Zn), and an additive element (X). The additive element (X) is one or more elements selected from tantalum (Ta), strontium (Sr), and niobium (Nb). In the sputtering target material, the atomic ratios between the elements satisfy the formulae (1) to (3) below. The sputtering target material has a relative density of 95% or more.

$$0.4 \leq \left(\text{In+X}\right) / \left(\text{In+Zn+X}\right) \leq 0.8 \qquad \text{(1)}$$

$$0.2 \leq \text{Zn} / \left(\text{In+Zn+X}\right) \leq 0.6 \qquad \text{(2)}$$

### CROSS REFERENCE TO RELATED APPLICATIONS

This application is a U.S. National Phase Application under 35 U.S.C. 371 of International Application No. PCT/JP2021/028640, filed on Aug. 2, 2021, which claims priority to Japanese Patent Application No. 2020-133080, filed on Aug. 5, 2020. The entire disclosures of the above applications are expressly incorporated by reference herein.

### BACKGROUND

### Technical Field

The present invention relates to a sputtering target material. The present invention also relates to an oxide semiconductor formed by using the sputtering target material.

### Related Art

In the technical field of thin-film transistors (hereinafter also referred to as “TFTs”) used in flat panel displays (hereinafter also referred to as “FPDs”), oxide semiconductors typified by In-Ga-Zn complex oxide (hereinafter also referred to as “1GZO”) have been attracting attention as substitutes for conventional amorphous silicon and put to practical use, for advanced FPDs. IGZO advantageously exhibits high field-effect mobility and small current leakage. As FPDs have been further advanced in recent years, materials that exhibit even higher field-effect mobility than that of IGZO have been proposed.

For example, US 2013/270109A1 and US 2014/102892A1 propose oxide semiconductors for TFTs, the oxide semiconductors being formed by using In-Zn-X complex oxides including elemental indium (In), elemental zinc (Zn), and an arbitrary element X. According to US 2013/270109A1 and US 2014/102892A1, these oxide semiconductors are formed by sputtering involving use of the In-Zn-X complex oxide as a target material.

In the technologies disclosed in US 2013/270109A1 and US 2014/102892A1, the target materials are produced using a powder-sintering method. However, target materials that are produced using the powder sintering method generally have a small relative density, and owing to this, the target materials tend to generate particles and also to crack when abnormal discharge occurs. As a result, problems may arise in the production of high-performance TFTs.

In addition, in the technical field of TFTs, there is a need for an oxide semiconductor that exhibits a field-effect mobility higher than that of IGZO.

Furthermore, in the technical field of TFTs, there is a need for an oxide semiconductor that exhibits a threshold voltage close to 0 V.

Therefore, it is an object of the present invention to provide a sputtering target material and an oxide semiconductor that can overcome the drawbacks of conventional technologies described above.

### SUMMARY

The present invention has been made to achieve the above-described object by providing a sputtering target material comprising an oxide including elemental indium (In), elemental zinc (Zn), and an additive element (X),
wherein the additive element (X) is one or more elements selected from tantalum (Ta), strontium (Sr), and niobium (Nb),
atomic ratios between the elements satisfy formulae (1) to (3):
$$0.4 \leq \left(\text{In+X}\right) / \left(\text{In+Zn+X}\right) \leq 0.8 \qquad \text{(1)}$$
$$0.2 \leq \text{Zn} / \left(\text{In+Zn+X}\right) \leq 0.6 \qquad \text{(2)}$$
$$0.001 \leq \text{X} / \left(\text{In+Zn+X}\right) \leq 0.015 \qquad \text{(3)}$$
where X represents the sum of ratios of the elements as the additive element, and
the sputtering target material has a relative density of 95% or more.

Also, the present invention provides an oxide semiconductor formed by using the above-described sputtering target material,
wherein the oxide semiconductor comprises an oxide including elemental indium (In), elemental zinc (Zn), and an additive element (X),
the additive element (X) is one or more elements selected from tantalum (Ta), strontium (Sr), and niobium (Nb), and
atomic ratio between the elements satisfy formulae (1) to (3):
$$0.4 \leq \left(\text{In+X}\right) / \left(\text{In+Zn+X}\right) \leq 0.8 \qquad \text{(1)}$$
$$0.2 \leq \text{Zn} / \left(\text{In+Zn+X}\right) \leq 0.6 \qquad \text{(2)}$$
$$0.001 \leq \text{X} / \left(\text{In+Zn+X}\right) \leq 0.015 \qquad \text{(3)}$$
where X represents the sum of ratios of the elements as the additive element.

Furthermore, the present invention provides a thin-film transistor having an oxide semiconductor,
wherein the oxide semiconductor comprises an oxide including elemental indium (In), elemental zinc (Zn), and an additive element (X),
the additive element (X) is one or more elements selected from tantalum (Ta), strontium (Sr), and niobium (Nb), and
atomic ratios between the elements satisfy formulae (1) to (3):
$$0.4 \leq \left(\text{In+X}\right) / \left(\text{In+Zn+X}\right) \leq 0.8 \qquad \text{(1)}$$
$$0.2 \leq \text{Zn} / \left(\text{In+Zn+X}\right) \leq 0.6 \qquad \text{(2)}$$
$$0.001 \leq \text{X} / \left(\text{In+Zn+X}\right) \leq 0.015 \qquad \text{(3)}$$
where X represents the sum of ratios of the elements as the additive element, and
the thin-film transistor has a field-effect mobility of 45 cm²/Vs or more.

### BRIEF DESCRIPTION OF THE DRAWINGS

FIG. 1 is a schematic diagram showing the structure of a thin-film transistor produced by using a sputtering target material of the present invention.

FIG. 2 is a chart showing the results of X-ray diffractometry of a sputtering target material obtained in Example 1.

FIG. 3 shows a scanning electron microscope image of the sputtering target material obtained in Example 1.

FIG. 4 shows another scanning electron microscope image of the sputtering target material obtained in Example 1.

FIG. 5 shows a chart and results of quantitative analysis obtained by performing EDX spectroscopy for the In₂O₃ phase of the sputtering target material obtained in Example 1.

FIG. 6 shows still another scanning electron microscope image of the sputtering target material obtained in Example 1.

FIG. 7 shows a chart and results of quantitative analysis obtained by performing EDX spectroscopy for the Zn₃In₂O₆ phase of the sputtering target material obtained in Example 1.

FIG. 8(a) is an image showing the result of EDX spectroscopy on the sputtering target material obtained in Example 1, and FIG. 8(b) is an image showing the result of EDX spectroscopy of a sputtering target material obtained in Comparative Example 1.

### DETAILED DESCRIPTION

Hereinafter, the present invention will be described based on preferred embodiments thereof. The present invention relates to a sputtering target material (hereinafter also referred to as the “target material”). The target material of the present invention comprises an oxide including elemental indium (In), elemental zinc (Zn), and an additive element (X). The additive element (X) is one or more elements selected from tantalum (Ta), strontium (Sr), and niobium (Nb). The target material of the present invention includes In, Zn, and the additive element (X) as metal elementals constituting the target material; however, in addition to these elements, the target material of the present invention may intentionally or unavoidably include a trace element as long as the effects of the present invention are not impaired. The trace element may be, for example, an element included in an organic additive or media materials for a ball mill or the like, which will be described later, and such an element may be mixed into the target material during the production thereof. Examples of the trace element that may be contained in the target material of the present invention include Fe, Cr, Ni. Al. Si, W, Zr, Na, Mg, K, Ca, Ti. Y, Ga, Sn, Ba, La, Ce, Pr, Nd, Pm, Sm, Eu, Gd, Tb, Dy, Ho, Er, Tm, Yb, Lu, and Pb. Usually, the content of a single trace element is preferably 100 ppm by mass (hereinafter also referred to as “ppm”) or less, more preferably 80 ppm or less, and even more preferably 50 ppm or less, relative to the total mass of the oxide including In, Zn, and X in the target material of the present invention. The total content of the trace elements is preferably 500 ppm or less, more preferably 300 ppm or less, and even more preferably 100 ppm or less. In the case where the target material of the present invention contains a trace element, the mass of the trace element is also included in the above-described total mass.

Preferably, the target material of the present invention is a sintered body including the above-described oxide. There is no particular limitation on the shape of the sintered body and the shape of the sputtering target material, and the sintered body and the sputtering target material may be in a conventionally known shape, such as a flat plate or a cylinder, for example,

In the target material of the present invention, the atomic ratios between the elemental metals included in the target material, namely, In, Zn, and X, are preferably in specific ranges, in view of improving the performance of an oxide semiconductor device formed from the target material.

Specifically, In and X preferably satisfy an atomic ratio represented by a formula (1) below. In the formula (1), X is the sum of the ratios of the elements as the additive element, and the same holds true for formulae (2) and (3) below.

$$0.4 \leq \left(\text{In+X}\right) / \left(\text{In+Zn+X}\right) \leq 0.8 \qquad \text{(1)}$$

Zn preferably satisfies an atomic ratio represented by the formula (2) below.

$$0.2 \leq \text{Zn} / \left(\text{In+Zn+X}\right) \leq 0.6 \qquad \text{(2)}$$

X preferably satisfies an atomic ratio represented by the formula (3) below.

$$0.001 \leq \text{X} / \left(\text{In+Zn+X}\right) \leq 0.015 \qquad \text{(3)}$$

When the atomic ratios between In, Zn, and X satisfy the formulae (1) to (3) above, a semiconductor device having an oxide thin film formed through sputtering that involves use of the target material of the present invention exhibits a high field-effect mobility, a low current leakage, and a threshold voltage close to 0 V. In view of making these advantages greater, In and X more preferably satisfy a formula (1-2), (1-3), (1-4), or (1-5) below.

$$0.43 \leq \left(\text{In+X}\right) / \left(\text{In+Zn+X}\right) \leq 0.79 \qquad \text{(1-2)}$$

$$0.48 \leq \left(\text{In+X}\right) / \left(\text{In+Zn+X}\right) \leq 0.78 \qquad \text{(1-3)}$$

$$0.53 \leq \left(\text{In+X}\right) / \left(\text{In+Zn+X}\right) \leq 0.75 \qquad \text{(1-4)}$$

$$0.58 \leq \left(\text{In+X}\right) / \left(\text{In+Zn+X}\right) \leq 0.70 \qquad \text{(1-5)}$$

From the same viewpoint as described above, Zn more preferably satisfies a formula (2-2), (2-3), (2-4), or (2-5) below, and X more preferably satisfies a formula (3-2), (3-3), (3-4), or (3-5) below.

$$0.21 \leq \text{Zn} / \left(\text{In+Zn+X}\right) \leq 0.57 \qquad \text{(2-2)}$$

$$0.22 \leq \text{Zn} / \left(\text{In+Zn+X}\right) \leq 0.52 \qquad \text{(2-3)}$$

$$0.25 \leq \text{Zn} / \left(\text{In+Zn+X}\right) \leq 0.47 \qquad \text{(2-4)}$$

$$0.30 \leq \text{Zn} / \left(\text{In+Zn+X}\right) \leq 0.42 \qquad \text{(2-5)}$$

$$0.0015 \leq \text{X} / \left(\text{In+Zn+X}\right) \leq 0.013 \qquad \text{(3-2)}$$

$$0.002 < \text{X} / \left(\text{In+Zn+X}\right) \leq 0.012 \qquad \text{(3-3)}$$

$$0.0025 \leq \text{X} / \left(\text{In+Zn+X}\right) \leq 0.010 \qquad \text{(3-4)}$$

$$0.003 \leq \text{X} / \left(\text{In+Zn+X}\right) \leq 0.009 \qquad \text{(3-5)}$$

As described above, one or more elements selected from Ta, Sr, and Nb are used as the additive element (X). One of these elements may be used alone, or two or more of these elements may be used in combination. In particular, it is preferable to use Ta as the additive element (X) in terms of the overall performance of an oxide semiconductor device produced by using the target material of the present invention and the economic efficiency in the production of the target material.

In the target material of the present invention, a formula (4) below with respect to the atomic ratio between In and X is preferably satisfied, in addition to the relationships of formulae (1) to (3) above. When the formula (4) is satisfied, an oxide semiconductor device having a further increased field-effect mobility and exhibiting a threshold voltage close to 0 V can be produced by using the target material of the present invention.

$$0.970 \leq \text{In} / \left(\text{In+X}\right) \leq 0.999 \qquad \text{(4)}$$

As is clear from the formula (4), an oxide semiconductor device produced by using the target material of the present invention has an increased field-effect mobility when X is included in an extremely small amount relative to the amount of In in the target material. This has been first found by the inventors of the present invention. In hitherto known conventional technologies (e.g., conventional technologies disclosed in US 2013/270109A1 and US 2014/102892A1), the amount of X relative to the amount of In is larger than that in the present invention.

Regarding In and X, the atomic ratio more preferably satisfies a formula (4-2), (4-3), or (4-4) below. When the formula (4-2), (4-3), or (4-4) is satisfied, an oxide semiconductor device produced by using the target material has an even higher field-effect mobility and exhibits a threshold voltage close to 0 V.

$$0.980 \leq \text{In} / \left(\text{In+X}\right) \leq 0.997 \qquad \text{(4-2)}$$

$$0.990 \leq \text{In} / \left(\text{In+X}\right) \leq 0.995 \qquad \text{(4-3)}$$

$$0.990 < \text{In} / \left(\text{In+X}\right) \leq 0.993 \qquad \text{(4-4)}$$

A large value of the field-effect mobility of the oxide semiconductor device produced by using the target material is preferable for the following reason: a large value of the field-effect mobility results in better transfer characteristics of a TFT device, which is an oxide semiconductor device, and therefore leads to an advanced FPD. More specifically, a TFT including an oxide semiconductor device formed by using the target material has a field-effect mobility (cm²/Vs) of preferably 45 cm²/Vs or more, more preferably 50 cm²/Vs or greater, even more preferably 60 cm²Ns or more, yet even more preferably 70 cm²/Vs or more, yet even more preferably 80 cm²/Vs or more, yet even more preferably 90 cm²/Vs or more, and yet even more preferably 100 cm²/Vs or more. A larger value of the field-effect mobility is more preferable in view of obtaining an advanced FPD; however, a field-effect mobility as high as about 200 cm²/VS can provide sufficiently satisfactory performance.

The proportions of the metals contained in the target material of the present invention are measured through ICP emission spectroscopy.

In addition to the atomic ratios between In, Zn, and X, the target material of the present invention is also characterized by its high relative density. More specifically, the target material of the present invention preferably has a relative density as high as 95% or more. In a case where the target material of the present invention has such a high relative density, the particle generation can be suppressed when sputtering by using the target material. From this viewpoint, the relative density of the target material of the present invention is more preferably 97% or more, even more preferably 98% or more, yet even more preferably 99% or more, yet even more preferably 100% or more, and yet even more preferably more than 100%. The target material of the present invention that has such a relative density is successfully produced using a method described later. The relative density is determined by the Archimedes’ method. A specific method will be described in detail in Examples given below.

The target material of the present invention is also characterized in that pores inside the target material have a small size and that the number of pores is small. More specifically, the target material of the present invention has a number of pores of 5 pores/1000 µm² or less, the pores having a diameter for the equivalent area of 0.5 µm or more and 20 µm or less. When sputtering is performed by using a target material with such a small number of pores, the particle generation can be advantageously suppressed. From this viewpoint, the target material of the present invention has a number of pores of preferably 3 pores/1000 µm² or less, even more preferably 2 pores/1000 µm² or less, yet even more preferably 1 pore/1000 µm² or less, yet even more preferably 0.5 pores/1000 µm² or less, and yet even more preferably 0.1 pores/1000 µm² or less, the pores having a diameter for the equivalent area of 0.5 µm or more and 20 µm or less. The target material of the present invention that has such a small number of pores is successfully produced using the method that will be described later. A specific measurement method will be described in detail in Examples given below.

In addition, the target material of the present invention is also characterized by a high strength. More specifically, the target material of the present invention preferably has a flexural strength as high as 100 MPa or more. When sputtering is performed by using the target material of the present invention that has such a high flexural strength, the target material is unlikely to crack even if unintentional abnormal discharge occurs during sputtering. From this viewpoint, the flexural strength of the target material of the present invention is more preferably 120 MPa or more, and even more preferably 150 MPa or more. The target material of the present invention that has such a flexural strength is successfully produced using the method that will be described later. The flexural strength is measured in accordance with JIS R1601. A specific measurement method will be described in detail in Examples given below.

The target material of the present invention is also characterized by a low bulk resistivity. A low bulk resistivity is advantageous since DC sputtering can be performed by using the target material. From this viewpoint, the bulk resistivity of the target material of the present invention at 25° C. is preferably 100 mΩ·cm or less, more preferably 50 mΩ·cm or less, even more preferably 10 mΩ·cm or less, yet even more preferably 5 mΩ·cm or less, yet even more preferably 4 mΩ·cm or less, yet even more preferably 3 mΩ·cm or less, yet even more preferably 2 mΩ·cm or less, and yet even more preferably 1.5 mΩ·cm or less. The target material of the present invention that has such a bulk resistivity is successfully produced using the method that will be described later. Bulk resistivity is measured using a DC four-point probe method. A specific measurement method will be described in detail in Examples given below.

The target material of the present invention is also characterized by small variations in the number of pores and small variations in bulk resistivity in the same plane of the target material. More specifically, the number of pores and the bulk resistivity are measured at any five points in the same plane of the target material of the present invention, for each of the number of pores and the bulk resistivity, the difference between the found value at each point and the arithmetic mean value of the found values at the five points is divided by the arithmetic mean value: the quotient is multiplied by 100; and the absolute value of the product is 20% or less. When sputtering is performed by using the target material having such small variations in the same plane as described above, the characteristics of the resulting film do not vary depending on the position of a glass substrate that is placed oppositely to the target material during sputtering. From this viewpoint, the aforementioned absolute value for the target material of the present invention is more preferably 15% or less, even more preferably 10% or less, yet even more preferably 5% or less, yet even more preferably 3% or less, and yet even more preferably 1% or less, for each of the number of pores and the bulk resistivity. The target material of the present invention that has small variations in the number of pores and small variations in bulk resistivity as described above is successfully produced using the method that will be described later.

Furthermore, the target material of the present invention is also characterized by small variations in the number of pores and small variations in bulk resistivity in the depth direction of the target material. More specifically, the target material of the present invention is ground in the depth direction from the surface by 1 mm at a time, and in each of the planes exposed through grinding, the number of pores and the bulk resistivity are measured; for each of the number of pores and the bulk resistivity, the difference between the found value at each point and the arithmetic mean value of the found values at the five points is divided by the arithmetic mean value: the quotient is multiplied by 100; and the absolute value of the product is 20% or less. From the same viewpoint as described above, the aforementioned absolute value for the target material of the present invention is more preferably 15% or less, even more preferably 10% or less, yet even more preferably 5% or less, yet even more preferably 3% or less, and yet even more preferably 1% or less, for each of the number of pores and the bulk resistivity. The target material of the present invention that has such small variations in the number of pores and such small variations in bulk resistivity is successfully produced using the method that will be described later.

In the target material of the present invention, the standard deviation of Vickers hardness in the same plane of the target material is preferably 50 or less. When the numerical value of the standard deviation is within this range, the target material is free of unevenness in density, crystal grain size, and composition and is thus preferred as a target material. The standard deviation of Vickers hardness in the same plane is more preferably 40 or less, even more preferably 30 or less, yet even more preferably 20 or less, and yet even more preferably 10 or less. The target material of the present invention that has such a Vickers hardness is successfully produced using the method that will be described later. Vickers hardness is measured in accordance with JIS-R-1610:2003. A specific measurement method will be described in detail in Examples given below.

The arithmetic mean roughness Ra (JIS-B-0601:2013) of the surface of the target material of the present invention can be adjusted as appropriate by changing, for example, the grit size of a grindstone used in grinding. When sputtering is performed by using a target material with a small arithmetic mean roughness Ra, abnormal discharge can be suppressed during sputtering advantageously. From this viewpoint, the arithmetic mean roughness Ra of the target material of the present invention is more preferably 3.2 µm or less, even more preferably 1.6 µm or less, yet even more preferably 1.2 µm or less, yet even more preferably 0.8 µm or less, yet even more preferably 0.5 µm or less, and yet even more preferably 0.1 µm or less. Arithmetic mean roughness Ra is measured using a surface roughness tester. A specific measurement method will be described in detail in Examples given below.

The target material of the present invention preferably has a maximum color difference ΔE* in the surface of 5 or less. The maximum color difference ΔE* in the depth direction of the target material is also preferably 5 or less. The term “color difference ΔE*” refers to a numerical index of the difference between two colors. When the numerical value of the maximum color difference ΔE* is within this range, the target material is free of unevenness in density, crystal grain size, and composition and is thus preferred as a target material. The maximum color difference AE* in the entire surface and the maximum color difference ΔE* in the depth direction are each more preferably 4 or less, even more preferably 3 or less, yet even more preferably 2 or less, and yet even more preferably 1 or less. The target material of the present invention that has such maximum color differences ΔE* is successfully produced using the method that will be described later. A specific measurement method will be described in detail in Examples given below.

As described above, the target material of the present invention comprises an oxide including In, Zn, and X. This oxide may include any of an oxide of In, an oxide of Zn, and an oxide of X. This oxide may also include a complex oxide of any two or more elements selected from the group consisting of In, Zn, and X. Specific examples of the complex oxide include, but are not limited to, an In-Zn complex oxide, a Zn-Ta complex oxide, an In-Ta complex oxide, an In-Nb complex oxide, a Zn-Nb complex oxide, an In-Nb complex oxide, an In-Sr complex oxide, a Zn-Sr complex oxide, an In-Sr complex oxide, an In-Zn-Ta complex oxide, an In-Zn-Nb complex oxide, and an In-Zn-Sr complex oxide.

In particular, the target material of the present invention preferably contains an In₂O₃ phase, which is an oxide of In, and a Zn₃In₂O₆ phase, which is a complex oxide of In and Zn, in view of increasing the density and strength of the target material and reducing the resistance of the target material. Whether the target material of the present invention contains the In₂O₃ phase and the Zn₃In₂O₆ phase can be determined by checking whether or not the In₂O₃ phase and the Zn₃In₂O₆ phase are found in X-ray diffractometry (hereinafter also referred to as “XRD′”) of the target material of the present invention. In the present invention, the In₂O₃ phase may contain a trace amount of elemental Zn.

More specifically, in XRD in which CuKα radiation is used as the X-ray source, the In₂O₃ phase exhibits the main peak in the range of 2θ = 30.38° or more and 30.78° or less, and the Zn₃In₂O₆ phase exhibits the main peak in the range of 2θ = 34.00° or more and 34.40° or less.

Furthermore, in the target material of the present invention, both the In₂O₃ phase and the Zn₃In₂O₆ phase preferably contain X. In particular, when X is homogeneously dispersed throughout the target material, the oxide semiconductor formed by using the target material of the present invention will contain X uniformly, and thus, a homogeneous oxide semiconductor film can be obtained. Whether X is contained in both the In₂O₃ phase and the Zn₃In₂O₆ phase can be determined through analysis by, for example, energy dispersive X-ray spectroscopy (hereinafter also referred to as “EDX”) or the like. A specific measurement method will be described in detail in Examples given below.

In the case where the In₂O₃ phase is found in the target material of the present invention by XRD, the In₂O₃ phase preferably has a crystal grain size within a specific range, in view of increasing the density and strength of the target material of the present invention and reducing the resistance of the target material. More specifically, the crystal grain size of the In₂O₃ phase is preferably 3.0 µm or less, more preferably 2.7 µm or less, and even more preferably 2.5 µm or less. The smaller the crystal grain size, the better. The lower limit value thereof is not specified, but is usually 0.1 µm or more.

In the case where the Zn₃In₂O₆ phase is found in the target material of the present invention by XRD, the Zn₃In₂O₆ phase preferably has a crystal grain size within a specific range, in view of increasing the density and strength of the target material of the present invention and reducing the resistance of the target material. More specifically, the crystal grain size of the Zn₃In₂O₆ phase is preferably 3.9 µm or less, more preferably 3.5 µm or less, even more preferably 3.0 µm or less, yet even more preferably 2.5 µm or less, yet even more preferably 2.3 µm or less, yet even more preferably 2.0 µm or less, and yet even more preferably 1.9 µm or less. The smaller the crystal grain size, the better. The lower limit value is not specified, but is usually 0.1 µm or more.

To set the crystal grain size of the In₂O₃ phase and the crystal grain size of the Zn₃In₂O₆ phase in the above-described ranges, the target material can be produced using, for example, the method that will be described later.

The crystal grain size of the In₂O₃ phase and the crystal grain size of the Zn₃In₂O₆ phase are measured by observing the target material of the present invention using a scanning electron microscope (hereinafter also referred to as “SEM”). A specific measurement method will be described in detail in Examples given below.

In relation to the crystal grain sizes described above, it is also preferable that the target material of the present invention should have a ratio of the area of the In₂O₃ phase to the unit area (hereinafter also referred to as the “In₂O₃ phase area ratio”) in a specific range, in view of reducing the resistance of the target material. More specifically, the In₂O₃ phase area ratio is preferably 10% or more and 70% or less, more preferably 20% or more and 70% or less, even more preferably 30% or more and 70% or less, and yet even more preferably 35% or more and 70% or less.

On the other hand, the ratio of the area of the Zn₃In₂O₆ phase to the unit area (hereinafter also referred to as the “Zn₃In₂O₆ phase area ratio”) is preferably 30% or more and 90% or less, more preferably 30% or more and 80% or less, even more preferably 30% or more and 70% or less, and yet even more preferably 30% or more and 65% or less.

To set the In₂O₃ phase area ratio and the Zn₃In₂O₆ phase area ratio in the above-described ranges, the target material can be produced using, for example, the method that will be described later. The In₂O₃ phase area ratio and the Zn₃In₂O₆ phase area ratio are determined by observing the target material of the present invention using an SEM. A specific measurement method will be described in detail in Examples given below.

Preferably, the In₂O₃ phase and the Ln₃In₂O₆ phase are homogeneously dispersed in the target material of the present invention. When these phases are homogeneously dispersed, a thin film formed by sputtering is advantageously free of unevenness in composition and variations in the film characteristics.

Evaluation of the dispersed state of a crystalline phase is performed using EDX. In a randomly selected area (437.5 µm × 625 µm) at a magnification of 200x on the target material, the In/Zn atomic ratio in the entire field of view is determined by EDX. Then, the same field of view is equally divided into 4 × 4, and the In/Zn atomic ratio in each divided field of view is obtained. The absolute value of the difference between the In/Zn atomic ratio in each divided field of view and the In/Zn atomic ratio in the entire field of view is divided by the In/Zn atomic ratio in the entire field of view, the quotient is multiplied by 100, and the resulting value is defined as a dispersion ratio (%). The degree of homogeneity of dispersion of the In₂O₃ phase and the Zn₃In₂O₆ phase is evaluated based on the magnitude of the obtained dispersion ratio. The closer the dispersion ratio is to zero, the more homogeneously dispersed the In₂O₃ phase and the Zn₃In₂O₆ phase are. The highest value of the dispersion ratios obtained in the sixteen fields of view is preferably 10% or less, more preferably 5% or less, even more preferably 4% or less, yet even more preferably 3% or less, yet even more preferably 2% or less, and yet even more preferably 1% or less.

Next, a preferred method for producing the target material of the present invention will be described. In the present production method, an oxide powder serving as the starting material of a target material is molded into a predetermined shape to obtain a compact, and the compact is then fired to obtain a sintered body as the target material. To obtain the compact, a method that has hitherto been known in the art can be used. In particular, casting or CIP (cold isostatic pressing) is preferably used because these methods are capable of producing a dense target material.

Casting is also called slip casting. To perform casting, first, a slurry containing starting material powders and an organic additive is prepared with a dispersion medium.

Oxide powders, hydroxide powders, or carbonate powders are suitably used as the starting material powders. As the oxide powders, an In oxide powder, a Zn oxide powder, and an X oxide powder are used. As the In oxide, In₂O₃ can be used, for example. As the Zn oxide, ZnO can be used, for example. As the X oxide powder, Ta₂O₅, SrO, and Nb₂O₅ can be used, for example. SrO may be in the form of SrCO₃ in air by combining with carbon dioxide, but in the sintering process, carbon dioxide dissociates from SrCO₃ to thereby form SrO.

In the present production method, firing is performed after all of the starting material powders are mixed. In contrast to this, in conventional technologies, for example, the technology disclosed in US 2014/102892A1, firing is performed after an In₂O₃ powder and a Ta₂O₅ powder are mixed, and then, the fired mixed powder and a ZnO powder are mixed, followed by firing again. In this method, particles constituting the powder become coarse as a result of firing in advance, and it is thus difficult to obtain a target material with a high relative density. On the other hand, in the present production method, firing is preferably performed after all of the In oxide powder, the Zn oxide powder, and the X oxide powder are mixed and molded at a normal temperature, whereby a dense target material with a high relative density can be easily obtained.

The amounts of the In oxide powder, the Zn oxide powder, and the X oxide powder used are preferably adjusted so that the atomic ratios between In, Zn, and X in the target material to be obtained satisfy the above-described ranges,

The particle size of each starting material powder is preferably 0.1 µm or more and 1.5 µm or less, in terms of the 50th percentile of the particle size on a volume basis, D₅₀, as determined using a laser diffraction scattering particle size distribution analyzing method. A dense target material with a high relative density can be easily obtained by using starting material powders that have particle sizes in this range.

The organic additive is a substance used to successively control the properties of the slurry and the compact. Examples of the organic additive include a binder, a dispersant, and a plasticizer. The binder is added to increase the strength of the compact. Any binder that is normally used to obtain a compact in a known powder sintering method can be used as the binder. An example of the binder is polyvinyl alcohol. The dispersant is added to improve the dispersibility of the starting material powders in the slurry. Examples of the dispersant include polycarboxylic acid-based dispersants and polyacrylic acid-based dispersants. The plasticizer is added to improve the plasticity of the compact. Examples of the plasticizer include polyethylene glycol (PEG), and ethylene glycol (EG).

There is no particular limitation on the dispersion medium used for preparing the slurry containing the starting material powders and the organic additive, and, according to the intended purpose, an appropriate dispersion medium to be used can be selected from water and water-soluble organic solvents such as alcohols. There is no particular limitation on the method for preparing the slurry containing the starting material powders and the organic additive, and, for example, the starting material powders, the organic additive, the dispersion medium, and zirconia balls may be placed into a pot and mixed by ball milling.

After the slurry is obtained in this manner, the slurry is poured into a mold, and the dispersion medium is then removed to thereby obtain the compact. Examples of the mold that can be used include metal molds and gypsum molds, and also resin molds, which are pressurized to remove the dispersion medium.

In CIP, the slurry as described above as the slurry for casting is spray-dried to obtain a dry powder. The obtained dry powder is filled into a mold and subjected to CIP.

After a compact is obtained in this manner, the compact is then fired. In general, the compact can be fired in an oxygen-containing atmosphere. In particular, firing is conveniently performed in the atmosphere. The firing temperature is preferably 1200° C. or more and 1600° C. or less, more preferably 1300° C. or more and 1500° C. or less, and even more preferably 1350° C. or more and 1450° C. or less. The firing time is preferably 1 hour or longer and 100 hours or shorter, more preferably 2 hours or longer and 50 hours or shorter, and even more preferably 3 hours or longer and 30 hours or shorter. The temperature increase rate is preferably 5° C./hour or more and 500° C./hour or less, more preferably 10° C./hour or more and 200° C./hour or less, and even more preferably 20° C./hour or more and 100° C./hour or less.

When the compact is fired, it is preferable to maintain, for a certain period of time in the firing process, the temperature at which a complex oxide of In and Zn (for example, a Zn₅In₂O₈ phase) is generated, in view of promoting sintering and generating a dense target material. More specifically, in the case where the starting material powders include an In₂O₃ powder and a ZnO powder, as the temperature increases, these powders react with each other to form a Zn₅In₂O₈ phase, which then changes to a Zn₄In₂O₇ phase and then to a Zn₃In₂O₆ phase. In particular, when the Zn₅In₂O₈ phase is generated, volume diffusion proceeds, and densification is promoted. Therefore, it is preferable to ensure that the Zn₅In₂O₈ phase is generated. From this viewpoint, in the course of temperature increase during firing, the temperature is preferably maintained in a range of 1000° C. or more and 1250° C. or less for a certain period of time, and more preferably maintained in a range of 1050° C. or more and 1200° C. or less for a certain period of time. The temperature is not necessarily maintained just at a certain specific temperature, and may be maintained at temperatures in a certain range. Specifically, when a specific temperature selected from the range of 1000° C. or more and 1250° C. or less is designated as T (°C), the temperature may be maintained at, for example, T±10° C., preferably T±5° C., more preferably T+3° C., and even more preferably T±1° C., as long as the temperature is in the range of 1000° C. or more and 1250° C. or less. The time period for which the temperature is maintained in this temperature range is preferably 1 hour or longer and 40 hours or shorter, and more preferably 2 hours or longer and 20 hours or shorter.

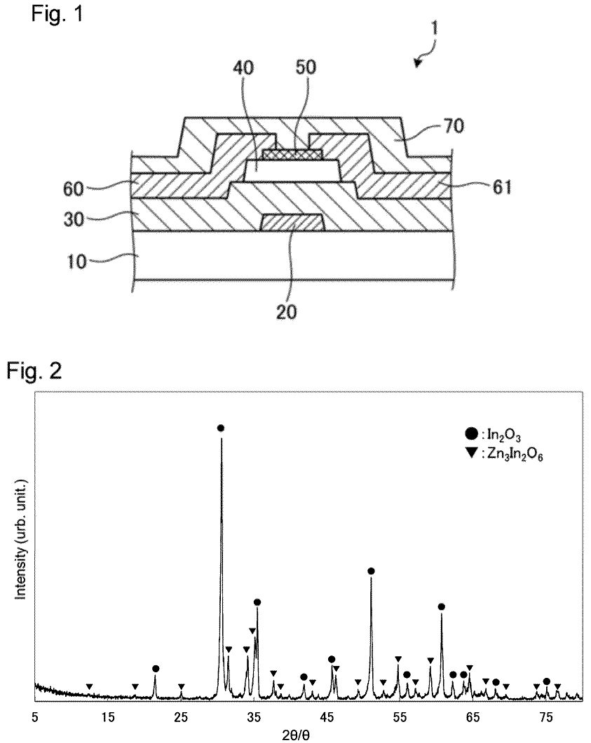

The target material obtained in this manner can be processed to predetermined dimensions through grinding or the like. A sputtering target can be obtained by joining such a target material to a substrate. The thus obtained sputtering target can be suitably used to produce an oxide semiconductor. For example, the target material of the present invention can be used to produce a TFT FIG. 1 schematically shows an example of a TFT device 1. The TFT device 1 shown in FIG. 1 is formed on a face of a glass substrate 10. A gate electrode 20 is formed on the face of the glass substrate 10, and a gate insulating film 30 is formed so as to cover the gate electrode 20. A source electrode 60. a drain electrode 61, and a channel layer 40 are arranged on the gate insulating film 30. An etching stopper layer 50 is disposed on the channel layer 40. A protective layer 70 is disposed at the top. In the TFT device 1 having this structure, the channel layer 40, for example, can be formed by using the target material of the present invention. In that case, the channel layer 40 includes an oxide including elemental indium (In), elemental zinc (Zn), and an additive element (X), and the atomic ratios between elemental indium (In), elemental zinc (Zn), and the additive element (X) satisfy the formula (1) above, and also the formulae (2) and (3) above.

An oxide semiconductor device produced by using the target material of the present invention preferably has an amorphous structure, in view of improving the performance of the device.

### EXAMPLES

Hereinafter, the present invention will be described in further detail by way of examples. However, the scope of the present invention is not limited to the examples given below. Unless otherwise specified, “%” means “mass%”.

### Example 1

An In₂O₃ powder with an average particle size D₅₀ of 0.6 µm, a ZnO powder with an average particle size D₅₀ of 0.8 µm, and a Ta₂O₅ powder with an average particle size D₅₀ of 0.6 µm were dry-mixed by ball milling using zirconia balls to thereby prepare a mixture of starting material powders. The average particle size D₅₀ of each powder was determined using a particle size distribution analyzer MT 3300 EXII manufactured by MicrotracBEL Corp. For the determination, water was used as the solvent, and the refractive index of the substance to be analyzed was regarded as 2.20. The mixing ratio between the powders was set such that the atomic ratios between In, Zn, and Ta were the values shown in Table 1.

To a pot in which the mixture of the starting material powders had been prepared, were added a binder in an amount of 0.2% relative to the mixed starting material powder, a dispersant in an amount of 0.6% relative to the mixed starting material powder, and water in an amount of 20% relative to the mixed starting material powder, and these were mixed by ball milling using zirconia balls to thereby prepare a slurry.

The resulting slurry was poured into a metal mold with a filter sandwiched. Then, water in the slurry was drained to thereby obtain a compact. This compact was fired to prepare a sintered body. The firing was performed in an atmosphere with an oxygen concentration of 20 vol%, at a firing temperature of 1400° C., for a firing time of 8 hours, and at a temperature increase rate of 50° C./hour and a temperature decrease rate of 50° C./hour. At the halfway stage in the process of firing, the temperature was maintained at 1100° C. for 6 hours to promote the formation of Zn₅In₂O₈.

The sintered body obtained in this manner was machined to obtain an oxide sintered body (target material) having a width of 210 mm, a length of 710 mm, and a thickness of 6 mm. A grindstone (grit size: #170) was used for the machining.

The variations in the number of pores and the variations in bulk resistivity of the target material in the same plane and in the depth direction were calculated using the above-described methods.

The results of the calculation of the variation in the number of pores in the same plane at any five points on the target material were 5.7%, 0.4%, 1.4%, 6.8%, and 2.2%, respectively. The results of the calculation of the variation in bulk resistivity in the same plane at any five points on the target material were 3.5%, 5.3%, 3.5%, 5.3%, and 3.5%, respectively.

The results of the calculation of the variation in the number of pores in the depth direction at any five points in the target material were 4.6%, 0.2%, 1.6%, 1.6%, and 1.6%, respectively. The results of the calculation of the variations in bulk resistivity in the depth direction at any five points in the target material were 3.5%, 5.3%, 3.5%, 5.3%, and 3.5%, respectively.

The number of pores per 1000 µm², the arithmetic mean roughness Ra, the maximum color difference ΔE* in the surface, and the maximum color difference ΔE* in the depth direction of the obtained target material were measured using the methods described later. The number of pores per 1000 µm² was 1.2. The arithmetic mean roughness Ra was 1.0 µm. The maximum color difference ΔE* in the surface was 1.1, and the maximum color difference ΔE* in the depth direction was 1.0.

### Examples 2 to 8

A target material was obtained in the same manner as in Example 1, except that the starting material powders in Examples 1 were mixed such that the atomic ratios between In, Zn, and Ta were the values shown in Table 1.

### Comparative Example 1

An In₂O₃ powder with an average particle size D₅₀ of 0.6 µm and a Ta₂O₅ powder with an average particle size D₅₀ of 0.6 µm were mixed such that the atomic ratio of elemental In to the sum of elemental In and elemental Ta. In/(In+Ta), was 0.993. The mixture was fed to a wet ball mill, and milled for 12 hours while mixing.

The resulting mixed slurry was taken out, filtered, and dried. The dried powder was placed in a firing furnace and heat-treated at 1000° C. for 5 hours in the atmosphere.

As a result, a mixed powder including elemental In and elemental Ta was obtained.

This mixed powder was mixed with a ZnO powder with an average particle size D₅₀ of 0.8 µm such that the atomic ratio [In/(In+Zn)] was 0.698. The resulting mixed powder was fed to a wet ball mill, and milled for 24 hours while mixing, to thereby obtain a slurry of the starting material powders. The slurry was filtered, dried, and granulated.

The resulting granulated product was press-molded and further molded by cold isostatic pressing under a pressure of 2000 kgf/cm².

The resulting compact was placed in a firing furnace and fired at 1400° C. for 12 hours under the conditions of atmospheric pressure and oxygen gas inflow, to thereby obtain a sintered body. The temperature increase rate was set to 0.5° C./min from room temperature to 400° C. and 1° C./min from 400° C. to 1400° C. The temperature decrease rate was set to 1° C./min.

A target material was obtained in the same manner as in Example except for the above.

### Comparative Example 2

A target material was obtained in the same manner as in Example 1 except that the Ta₂O₅ powder was not used, and that the starting material powders were mixed such that the atomic ratios between In and Zn were the values shown in Table 2.

### Examples 9 to 13

A target material was obtained in the same manner as in Example 1 except that the starting material powders were mixed such that the atomic ratios between In, Zn, and Ta were the values shown in Table 2.

### Example 14

A target material was obtained in the same manner as in Example 1 except that a Nb₂O₅ powder with an average particle size D₅₀ of 0.7 µm was used instead of the Ta₂O₅ powder, and that the starting material powders were mixed such that the atomic ratios between In, Zn, and Nb were the values shown in Table 2.

### Example 15

A target material was obtained in the same manner as in Example 1 except that a SrCO₃ powder with an average particle size D₅₀ of 1.5 µm was used instead of the Ta₂O₅ powder, and that the starting material powders were mixed such that the atomic ratios between In. Zn, and Sr were the values shown in Table 2.

### Example 16

A target material was obtained in the same manner as in Example 1 except that a Ta₂O₅ powder, an Nb₂O₅ powder, and an SrCO₃ powder were mixed, instead of the Ta₂O₅ powder used in Example 1, such that the atomic ratios between In, Zn, Ta, Nb, and Sr were the values shown in Table 2. The mole ratio between Ta, Nb, and Sr was Ta:Nb:Sr = 3:1:1.

The proportions of the metals in the target materials obtained in the examples and the comparative examples were determined by ICP emission spectroscopy. It was confirmed that the atomic ratios between In, Zn, and Ta were the same as the ratios for the starting materials shown in Table 1.

### Evaluation 1

The relative density, flexural strength, bulk resistivity, and Vickers hardness of each of the target materials obtained in the examples and the comparative examples were determined using the following methods. Each of the target materials obtained in the examples and the comparative examples was subjected to XRD to check whether or not the In₂O₃ phase and the Zn₃In₂O₆ phase were present. In addition, each of the target materials obtained in the examples and the comparative examples was observed using an SEM, and the crystal grain size of the In₂O₃ phase, the crystal grain size of the Zn₃In₂O₆ phase, the In₂O₃ phase area ratio, and the Zn₃In₂O₆ phase area ratio were determined using the following methods. Furthermore, whether or not the In₂O₃ phase and the Zn₃In₂O₆ phase found by the SEM observation contained the additive element (X) was determined by EDX. Tables 1 and 2 below and FIGS. 2 to 7 show the results.

### Relative Density

The mass of the target material in air was divided by its volume (mass of target material in water / specific gravity relative to water at measurement temperature), and the percentage of the quotient relative to the theoretical density ρ (g/cm³), which is defined as the equation (i) below, was obtained. This percentage was used as the relative density (unit: %):

$$\text{ρ} = \sum {\left(\left(\text{Ci} / 100\right) / \text{ρ} \text{i}\right)}^{- 1} \qquad \text{(i)}$$

where Ci represents the content (mass%) of a constituent material in the target material, and ρi represents the density (g/cm³) of the constituent material corresponding to Ci.

In the case of the present invention, the contents (mass%) of constituent materials in the target material were considered to be the contents of In₂O₃, ZnO, Ta₂O₅, Nb₂O₅, and SrO, and, for example, the theoretical density ρ can be calculated by applying the followings to the equation (i).
C1: content of In₂O₃ in the target material, mass%
ρ1: density of In₂O₃ (7.18 g/cm³)
C2: content of ZnO in the target material, mass%
ρ2: density of ZnO (5.60 g/cm³)
C3: content of Ta₂O₅ in target material, mass%
ρ3: density of Ta₂O₅ (8.73 g/cm³)
C4: content of Nb₂O₅ in the target material, mass%
ρ4: densitny Nb₂O₅ (4.60 g/cm³)
C5: content of SrO in the target material, mass%
ρ5: density of SrO (4.70 g/cm³)

The contents (mass%) of In₂O₃, ZnO. Ta₂O₅, Nb₂O₅, and SrO can be obtained from the results of analyzing the individual elements in the target material by ICP emission spectroscopy.

### Number of Pores Per 1000 Μm²

A cut surface obtained by cutting the target material was polished in a stepwise manner using pieces of emery paper with grit sizes of #180, #400, #800, #1000, and #2000, and finally buffed to a mirror finish. The mirror-finished surface was observed using an SEM. SEM images of randomly chosen five fields of view with an area of 218.7 µm × 312.5 µm at a magnification of 400x were captured.

The SEM images were analyzed using a piece of image processing software, ImageJ 1.51k (http://imageJ.nih.gov/ij/, provided by U.S. National Institutes of Health (NIH)). The specific procedure is as follows.

First, in each of the images, lines were drawn along pores. After all the drawings were completed, grain analysis was performed (Analyze → Analyze Particles) to obtain the number of pores and the areas of the individual pores. After that, from the areas of the individual pore, the respective diameters for the equivalent area were calculated. The total number of pores with a diameter for the equivalent area of 0.5 to 20 µm observed in the five fields of view was divided by the total area of the five fields of view, and the thus obtained number of pores was converted to the number of pores per 1000 µm².

### Flexural Strength

For the measurement, Autograph (registered trademark) AGS-500B manufactured by Shimadzu Corporation was used. A specimen (with a total length of 36 mm or more, a width of 4.0 mm, and a thickness of 3.0 mm) cut from the target material was used, and measurement was performed according to the three-point flexural strength measurement method specified in JIS-R-1601 (Testing method for flexural strength (modulus of rupture) of fine ceramics).

### Bulk Resistivity

Measurement was performed according to the DC four-point probe method specified in the JIS standard using Loresta (registered trademark) HP MCP-T410 manufactured by Mitsubishi Chemical. For the measurement, a probe (in-line four-point probe TYPE ESP) was placed in contact with the surface of the target material after processing, and the AUTO RANGE mode was used. The bulk resistivity was measured at a total of five points, where one point was near the center of the target material and the other points were at the four corners of the target material. An arithmetic mean value of the found values was used as the bulk resistivity of the target material.

### Arithmetic Mean Roughness Ra

Measurement was performed using a surface roughness tester (SJ-210 manufactured by Mitutoyo Corporation). A surface roughness was measured at five points on a sputtering surface of the target material, and an arithmetic mean value of the found values was used as the arithmetic mean roughness Ra of the target material.

### Maximum Color Difference

The in-plane color difference ΔE^{∗} was determined in the following manner. The surface of the machined target material was analyzed at intervals of 50 mm in the x-axis direction and the y-axis direction using a color difference meter (chrome meter CR-300 manufactured by Konica Minolta, Inc.), and L^{∗}, a^{∗}, and b^{∗} values of each analysis point were evaluated in the CIE1976 L^{∗}a^{∗}b^{∗} color space. Then, the color difference ΔE^{∗} was obtained using an equation (ii) below from the differences ΔL^{∗}, Δa^{∗}. and Ab^{∗} between the two L^{∗} values, the two a^{∗} values, and the two b^{∗} values, respectively, of two of the measurement points. The color differences ΔE^{∗} were obtained for all the combinations of two measurement points, and the greatest value of the plurality of color differences ΔE^{∗} obtained was used as the maximum color difference ΔE^{∗} in the surface

$$\text{Δ} \text{E*} = {\left({\left(\text{Δ} \text{L*}\right)}^{2} + {\left(\text{Δ} \text{a*}\right)}^{2} + {\left(\text{Δ} \text{b*}\right)}^{2}\right)}^{1 / 2} \qquad \text{(ii)}$$

The color difference ΔE^{∗} in the depth direction was determined in the following manner. Any suitable portion of the machined target material was machined by 1 mm at a time. Analysis was performed at each depth using a color difference meter until a central portion of the target material was reached. L^{∗}, a^{∗}, and b^{∗} values measured at each depth were evaluated in the CIE1976 L^{∗}a^{∗}b^{∗} color space. Then, a color difference ΔE^{∗} was obtained from the differences ΔL^{∗}, Δa^{∗}, and Δb^{∗} between the two L^{∗} values, the two a^{∗} values, and the two b^{∗} values, respectively, of two of the measurement depths. The color differences ΔE^{∗} were obtained for all the combinations of two measurement depths, and the greatest value of the plurality of color differences ΔE^{∗} obtained was used as the maximum color difference ΔE^{∗} in the depth direction.

### Vickers Hardness

Measurement was performed using a Vickers hardness tester MHT-1 from Matsuzawa Co., Ltd. A cut surface obtained by cutting the target material was polished in a stepwise manner using pieces of emery paper with grit sizes of #180, #400, #800, #1000, and #2000, and finally buffed to a mirror finish. The mirror-finished surface was used as a measurement surface. The surface on the other side than the measurement surface side was polished using a piece of emery paper with a grit size of #180 so that the surface on the other side was parallel to the measurement surface, thereby obtaining a test specimen. On the test specimen, the Vickers hardness was measured under a load of 1 kgf according to the hardness measurement method specified in JIS-R-1610:2003 (Test methods for hardness of fine ceramics). Measurement was performed at ten different positions in a single test specimen, and an arithmetic mean value of the found values was used as the Vickers hardness of the target material. Also, the standard deviation of Vickers hardness was calculated from the measured values.

### Conditions for XRD

Smart Lab (registered trademark) available from Rigaku Corporation was used for XRD. The conditions for XRD were as follows. FIG. 2 shows the results of an XRD of the target material obtained in Example 1.
X-ray source: CuKα radiation
Tube voltage: 40 kV
Tube current: 30 mA
Scan rate: 5 deg/min
Step: 0.02 deg
Scan range: 20 = 5 deg to 80 deg

### Crystal Grain Size of In₂O₃ Phase, Crystal Grain Size of Zn₃In₂O₆ Phase, In₂O₃ Phase Area Ratio, and Zn₃In₂O₆ Phase Area Ratio

Using a scanning electron microscope SU3500 manufactured by Hitachi High-Technologies Corporation, the surface of the target material was observed, and the phases constituting the crystal and the crystal shapes were evaluated.

Specifically, a cut surface obtained by cutting the target material was polished in a stepwise manner using pieces of emery paper with grit sizes of #180, #400, #800, #1000, and #2000, and finally buffed to a mirror finish. The mirror-finished surface was subjected to SEM observation. For evaluation of the crystal shape, SEM images were obtained by capturing BSE-COMP images of randomly chosen ten fields of view, with an area of 87.5 µm × 125 µm at a magnification of 1000x.

The SEM images were analyzed using the image processing software, ImageJ 1.51k (http://imageJ.nih.gov/ij/, provided by U.S. National Institutes of Health (NIH)). The specific procedure is as follows.

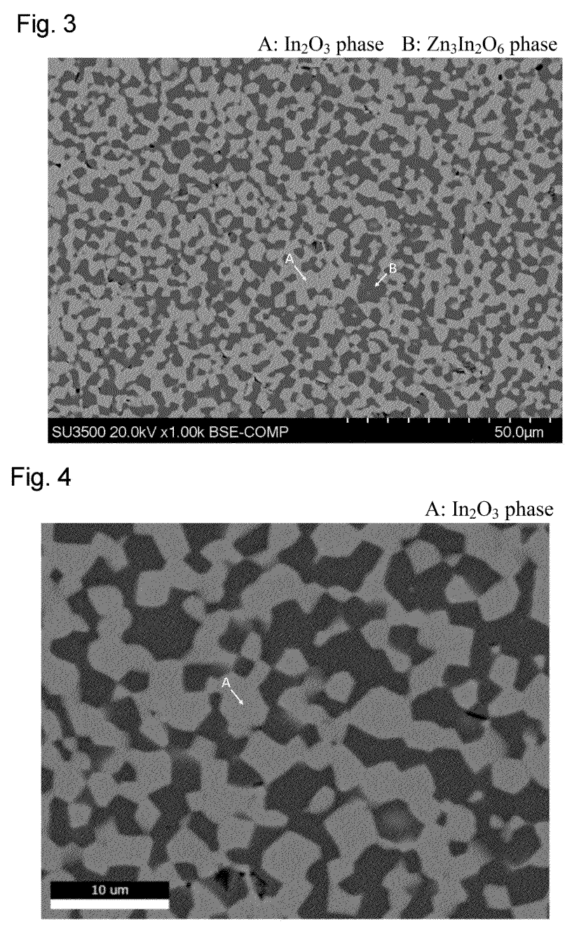

The sample used for SEM imaging was subjected to thermal etching at 1100° C. for 1 hour, and the resulting sample was observed using SEM to thereby obtain an image shown in FIG. 3, in which grain boundaries were revealed. In the image, lines were drawn along the grain boundaries of the In₂O₃ phase (regions A, which appear white, in FIG. 3). After all the drawings were completed, grain analysis was performed (Analyze → Analyze Particles) to obtain the areas of the grains. Then, the diameters for the equivalent area were calculated from the areas of the grains. An arithmetic mean value of the diameters for the equivalent area of all the grains determined in the ten fields of view was used as the crystal grain size of the In₂O₃ phase. Subsequently, lines were drawn along the grain boundaries of the Zn₃In₂O₆ phase (regions B, which appear black, in FIG. 3), and analysis was performed in the same manner as above to obtain the areas of the grains. The diameters for the equivalent area were calculated from the areas of the grains. An arithmetic mean value of the diameters for the equivalent area of all the grains determined in the ten fields of view was used as the crystal grain size of the Zn₃In₂O₆ phase.

In addition, for each of the BSE-COMP images before the thermal etching, in which no grain boundaries were revealed, grain analysis was performed to determine the ratio of the area of the In₂O₃ phase to the total area. An arithmetic mean value of the area ratios for all the grains determined in the ten fields of view was used as the In₂O₃ phase area ratio. The Zn₃In₂O₆ phase area ratio was obtained by subtracting the In₂O₃ phase area ratio from 100.

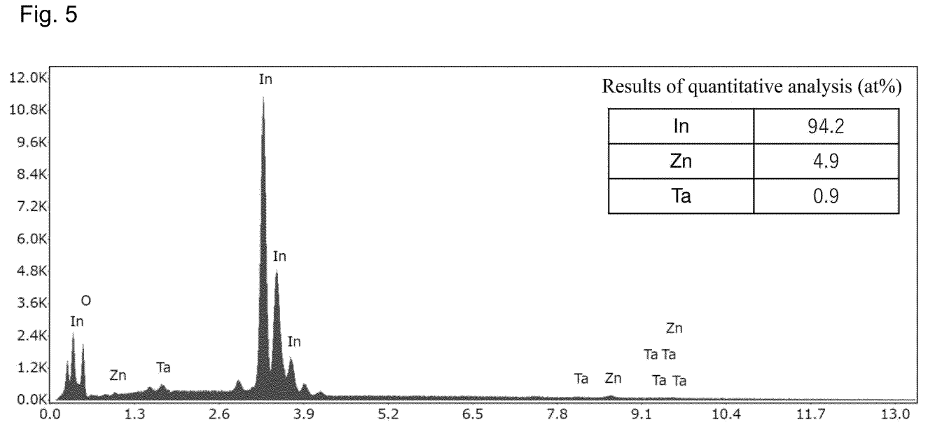

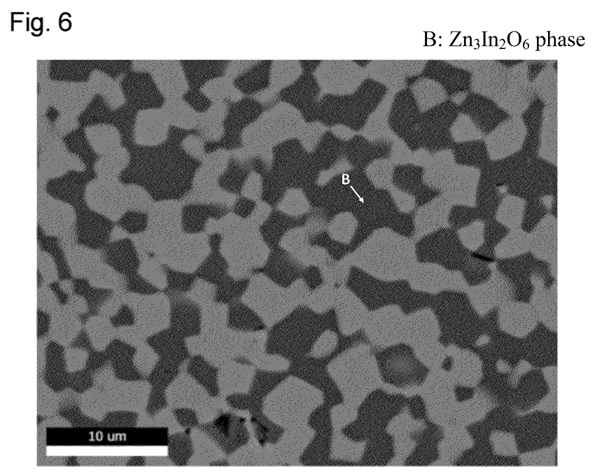

Note that FIGS. 4 and 6 are enlarged images of FIG. 3.

### Presence/Absence of Additive Element (X) and Quantitative Determination of Additive Element (X)

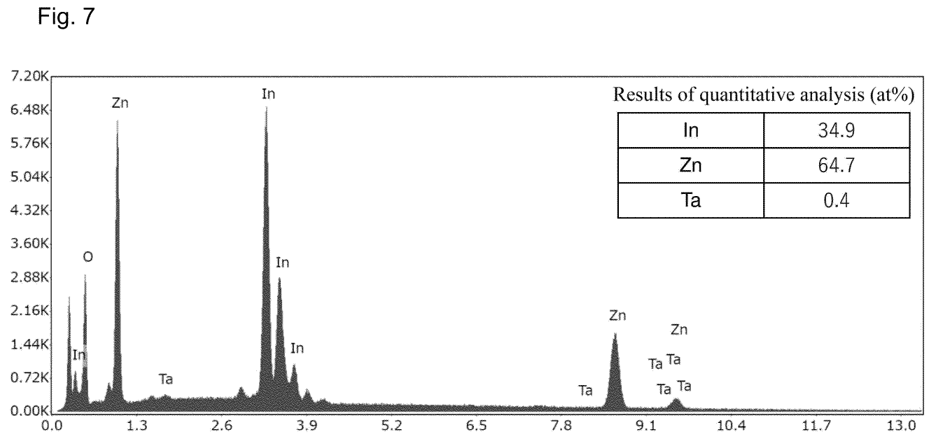

Using an energy dispersive X-ray spectrometer (Octane Elite Plus manufactured by EDAX), spectral information was obtained by point analysis at any appropriate positions in the In₂O₃ phase and the Zn₃In₂O₆ phase identified through the SEM observation, and whether or not the additive element (X) was contained was checked. FIGS. 5 and 7 show the results.

### Evaluation 2

TFT devices 1 shown in FIG. 1 were produced by photolithography by using the target materials of the examples and the comparative examples.

To produce the TFT device 1, first, a Mo thin film serving as a gate electrode 20 was formed on a glass substrate 10 (OA-10 manufactured by Nippon Electric Glass Co., Ltd.) using a DC sputtering apparatus. Next, a SiOx thin film serving as a gate insulating film 30 was formed under the following conditions.
Deposition system: plasma CVD system PD-2202L manufactured by Samco Inc.
Gas for deposition: SiH₄/N₂O/N₂ mixed gas
Pressure for deposition: 110 Pa
Temperature of substrate: 250° C. to 400° C.

Next, film formation by sputtering was performed under the following conditions by using each of the target materials obtained in the examples and the comparative examples, to thereby give a thin film with a thickness of about 10 to 50 nm as a channel layer 40.
Deposition system: DC sputtering equipment SML-464 manufactured by Tokki Corporation
Ultimate vacuum pressure: less than 1×10⁻⁴ Pa
Sputter gas: Ar/O₂ mixed gas
Pressure of sputter gas: 0.4 Pa
Partial pressure of O₂ gas: 50%
Temperature of substrate: room temperature
Sputtering power: 3 W/cm²

Furthermore, a SiOx thin film serving as an etching stopper layer 50 was formed using the plasma CVD system above. Next, Mo thin films serving as a source electrode 60 and a drain electrode 61 were formed using the DC sputtering equipment above. Then, a SiOx thin film serving as a protective layer 70 was formed using the plasma CVD system above. Finally, heat treatment was performed at 350° C.

For the TFT devices 1 obtained in this manner, their transfer characteristics at a drain voltage Vd = 5 V were determined. The transfer characteristics are the field-effect mobility µ (cm²/Vs), the SS (Subthreshold Swing) value (V/dec), and the threshold voltage Vth (V). The transfer characteristics were determined using Semiconductor Device Analyzer B1500A manufactured by Agilent Technologies. Tables 1 and 2 below show the results. Although not shown in the tables, the inventors of the present invention confirmed by XRD that the channel layer 40 of each of the TFT devices 1 obtained in the examples had an amorphous structure.

The field-effect mobility is the channel mobility obtained from the change in drain current relative to gate voltage when the drain voltage is kept constant in the saturation region of the working of MOSFET (Metal-Oxide-Semiconductor Field-Effect Transistor). The larger the value of the field-effect mobility, the better the transfer characteristics.

The SS value is the gate voltage necessary to raise the drain current by one digit near the threshold voltage. The smaller the SS value, the better the transfer characteristics.

The threshold voltage is the voltage at which the drain current reaches 1 nA, when a positive voltage and a positive or negative voltage are applied to the drain electrode and the gate electrode, respectively, to allow the drain current to flow. The threshold voltage preferably close to 0 V. More specifically, the threshold voltage is more preferably –2 V or more, even more preferably –1 V or more, and yet even more preferably 0 V or more. Also, the threshold voltage is more preferably 3 V or less, even more preferably 2 V or less, and yet even more preferably 1 V or less. Specifically, the threshold voltage is more preferably –2 V or more and 3 V or less, even more preferably –1 V or more and 2 V or less, and yet even more preferably 0 V or more and 1 V or less.

TABLE 1

| | | Ex. 1 | Ex 2 | Ex. 3 | Ex 4 | Ex. 5 | Ex 6 | Ex. 7 | Ex. 8 | Com. Ex. 1 | Com. Ex. 2 |
|---|---|---|---|---|---|---|---|---|---|---|---|
| (In+X)/(In+Zn+X) | | 0.700 | 0.700 | 0.700 | 0.700 | 0.800 | 0.650 | 0.600 | 0.500 | 0.700 | 0.700 |
| Zn/(In+Zn+X) | | 0.300 | 0.300 | 0.300 | 0.300 | 0.200 | 0.350 | 0.400 | 0.500 | 0.300 | 0.300 |
| X/(In+Zn+X) | | 0.005 | 0.003 | 0.007 | 0.010 | 0.005 | 0.005 | 0.005 | 0.005 | 0.005 | 0.000 |
| In/(In+X) | | 0.993 | 0.996 | 0.990 | 0.986 | 0.994 | 0.992 | 0.992 | 0.990 | 0.993 | 1.000 |
| Additive element (X) | | Ta | Ta | Ta | Ta | Ta | Ta | Ta | Ta | Ta | No |
| Firing of starting material powder | | No | No | No | No | No | No | No | No | Yes | No |
| Maintaining of temperature at halfway stage of firing | | Yes | Yes | Yes | Yes | Yes | Yes | Yes | Yes | No | Yes |
| Relative density [%] | | 98.2 | 98.4 | 98.7 | 98.7 | 98.8 | 98.5 | 98.4 | 98.5 | 92.8 | 98.8 |
| Flexural strength [MPa] | | 160 | 158 | 159 | 161 | 157 | 161 | 166 | 164 | 64 | 158 |
| Bulk resistivity [mΩ·cm] | | 1.1 | 1.2 | 1.2 | 1.3 | 1.1 | 1.2 | 1.4 | 1.8 | 4.2 | 38 |
| Vickers hardness [HV1] | | 570 | 565 | 575 | 588 | 609 | 521 | 487 | 447 | 479 | 542 |
| Standard deviation of hardness | | 9 | 19 | 15 | 11 | 14 | 8 | 19 | 11 | 86 | 16 |
| Crystal grain size [µm] | In₂O₃ phase | 2.2 | 1.9 | 2.4 | 2.3 | 2.2 | 2.0 | 1.8 | 1.7 | 3.1 | 2.0 |
| | Zn₃In₂O₆ phase | 2.1 | 2.0 | 2.1 | 2.2 | 1.9 | 2.3 | 2.5 | 3.4 | 4.0 | 1.9 |
| Area ratio [%] | In₂O₃ phase | 48.4 | 50.3 | 53.7 | 50.7 | 66.2 | 43.0 | 35.6 | 20.8 | 32.4 | 54.5 |
| | Zn₃In₂O₆ phase | 51.6 | 49.7 | 46.3 | 49.3 | 33.8 | 57.0 | 64.4 | 79.2 | 67.6 | 45.5 |
| Transfer characteristics | Field-effect mobility µ [cm²/Vs] | 71.8 | 97.8 | 56.4 | 76.8 | 48.4 | 78.2 | 78.9 | 70.2 | 34.5 | Conduct ive |
| | Threshold voltage Vth [V] | 0.3 | 0.1 | 0.5 | -0.1 | 0.0 | 0.8 | 1.2 | 2.5 | -4.2 | Conduct ive |
| | SS value [V/dec] | 0.26 | 0.26 | 0.36 | 0.32 | 0.19 | 0.32 | 0.35 | 0.27 | 0.33 | Conduct ive |

TABLE 2

| | | Ex 9 | Ex. 10 | Ex. 11 | Ex. 12 | Ex. 13 | Ex. 14 | Ex. 15 | Ex. 16 |
|---|---|---|---|---|---|---|---|---|---|
| (In+X)/(In+Zn+X) | | 0.700 | 0.700 | 0.750 | 0.600 | 0.400 | 0.700 | 0.700 | 0.700 |
| Zn/(In+Zn+X) | | 0.300 | 0.300 | 0.250 | 0.400 | 0.600 | 0.300 | 0.300 | 0.300 |
| X/(In+Zn+X) | | 0.001 | 0.002 | 0.005 | 0.003 | 0.005 | 0.005 | 0.005 | 0.005 |
| In/(In+X) | | 0.999 | 0.997 | 0.993 | 0.995 | 0.988 | 0.993 | 0.993 | 0.993 |
| Additive element (X) | | Ta | Ta | Ta | Ta | Ta | Nb | Sr | Ta, Nb, Sr |
| Firing of starting material powder | | No | No | No | No | No | No | No | No |
| Maintaining of temperature at halfway stage of firing | | Yes | Yes | Yes | Yes | Yes | Yes | Yes | Yes |
| Relative density [%] | | 98.5 | 98.4 | 98.7 | 98.5 | 98.9 | 98.6 | 98.8 | 98.7 |
| Flexural strength [MPa] | | 159 | 161 | 160 | 165 | 158 | 158 | 157 | 159 |
| Bulk resistivity [mΩ·cm] | | 1.1 | 1.2 | 1.2 | 1.4 | 22.0 | 1.1 | 3.8 | 1.2 |
| Vickers hardness [HV1] | | 535 | 548 | 595 | 484 | 323 | 562 | 558 | 565 |
| Standard deviation of hardness | | 18 | 16 | 17 | 8 | 12 | 10 | 11 | 9 |
| Crystal grain size [µm] | In₂O₃ phase | 2.0 | 2.0 | 2.2 | 1.7 | 1.7 | 2.1 | 2.0 | 2.2 |
| | Zn₃In₂O₆ phase | 2.0 | 2.0 | 2.0 | 2.6 | 10.7 | 2.0 | 2.0 | 2.1 |
| Area ratio [%] | In₂O₃ phase | 50.5 | 50.4 | 57.3 | 35.2 | 1.5 | 49.5 | 50.1 | 49.8 |
| | Zn₃In₂O₆ phase | 49.5 | 49.6 | 42.7 | 64.8 | 98.5 | 50.5 | 49.9 | 50.2 |
| Transfer characteris tics | Field-effect mobility µ [cm²/Vs] | 101.2 | 99.8 | 68.2 | 62.8 | 65.4 | 76.2 | 65.2 | 77.1 |
| | Threshold voltage Vth [V] | -0.1 | -0.1 | 0.0 | 1.3 | 5.3 | 0.5 | 0.8 | 0.1 |
| | SS value [V/dec] | 0.28 | 0.25 | 0.26 | 0.24 | 0.26 | 0.33 | 0.28 | 0.27 |

From the results shown in Tables 1 and 2, it can be seen that the TFT devices produced by using the target materials obtained in the examples have excellent transfer characteristics. Although the number of pores per 1000 µm², the variations in the number of pores, the variations in bulk resistivity, the arithmetic mean roughness Ra, the maximum color difference, and the In/Zn atomic ratio are not shown in Tables 1 and 2, the target materials obtained in Examples 2 to 16 also exhibited similar results to those of Example 1.

Furthermore, as is clear from the results shown in FIG. 2, the target material obtained in Example 1 contained the In₂O₃ phase and the Zn₃In₂O₆ phase. Although not shown in the drawings, the target materials obtained in Examples 2 to 16 also exhibited similar results.

Furthermore, as is clear from the results shown in FIGS. 5 and 7, Ta was contained in both of the In₂O₃ phase and the Zn₃In₂O₆ phase in the target material obtained in Example 1. Although not shown in the drawings, the target materials obtained in Examples 2 to 16 also exhibited similar results.

### Evaluation 3

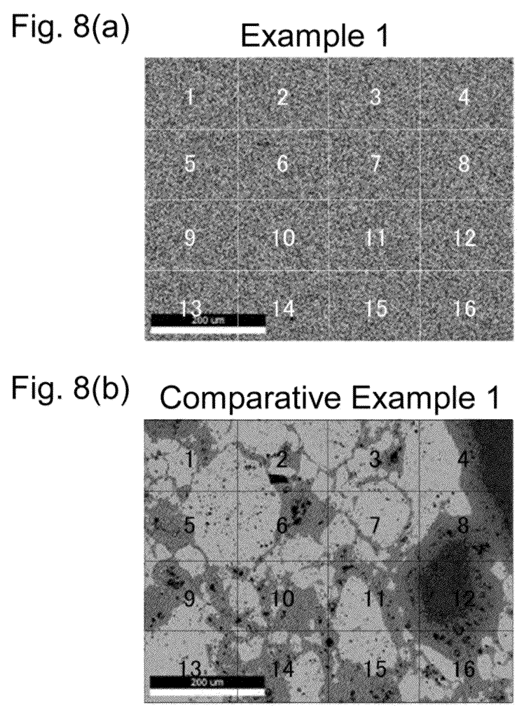

The dispersion ratios of the In₂O₃ phase and the Zn₃In₂O₆ phase in each of the target materials obtained in Example 1 and Comparative Example 1 were determined using the method described hereinabove. Table 3 below and FIGS. 8(a) and 8(b) show the results.

TABLE 3

Dispersion state (dispersion ratio) of In₂O₃ phase and Zn₃In₂O₆ phase

| | | | | | | | | | | | | | | | | |
|---|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 | 16 |
| Ex. 1 | 1.3% | 0.9% | 0.2% | 1.7% | 0.1% | 3.2% | 1.8% | 2.2% | 3.2% | 2.5% | 2.6% | 1.5% | 1.3% | 3.3% | 0.6% | 2.3% |
| Com. Ex. 1 | 85.8% | 243.4% | 145.1% | 64 1% | 105.2% | 83.4% | 166.8% | 70.3% | 6 1% | 2.9% | 22.8% | 82.2% | 337.9% | 6.2% | 2.1% | 8.1% |

From the result shown in FIG. 8(a), it can be seen that the In₂O₃ phase and the Zn₃In₂O₆ phase were homogeneously dispersed in the target material obtained in Example 1. As shown in Table 3, the dispersion ratios in the sixteen field of views in Example 1 were at most 3.3%, which supported the homogeneous dispersion of the In₂O₃ phase and the Zn₃In₂O₆ phase.

In contrast, it can be seen from the result shown in FIG. 8(b) that the In₂O₃ phase and the Zn₃In₂O₆ phase were inhomogeneously dispersed in the target material obtained in Comparative Example 1.

Although not shown in the tables, the inventors of the present invention confirmed that the dispersion ratios in the sixteen fields of view were at most 10% or less in the target materials obtained in Examples 2 to 16 as well.

### INDUSTRIAL APPLICABILITY

As described in detail above, using the sputtering target material of the present invention enables the suppression of the particle generation and the suppression of cracking otherwise caused by abnormal discharge, and consequently, enables production of a TFT having high field-effect mobility with ease.

1. A sputtering target material comprising an oxide including elemental indium (In), elemental zinc (Zn), and an additive element (X),
wherein the additive element (X) is one or more elements selected from tantalum (Ta), strontium (Sr), and niobium (Nb),
atomic ratios between the elements satisfy formulae (1) to (3):
$$0.4 \leq \left(\text{ln+X}\right) / \left(\text{ln+Zn+X}\right) \leq 0.8 \qquad \text{(1)}$$
$$0.2 \leq \text{Zn} / \left(\text{ln+Zn+X}\right) \leq 0.6 \qquad \text{(2)}$$
$$0.001 \leq \text{X} / \left(\text{ln+Zn+X}\right) \leq 0.015 \qquad \text{(3)}$$
where X represents the sum of ratios of the elements as the additive element, and
the sputtering target material has a relative density of 95% or more.

2. The sputtering target material according to claim 1, wherein the additive element (X) is tantalum (Ta).

3. The sputtering target material according to claim 1, wherein the sputtering target material has a flexural strength of 100 MPa or more.

4. The sputtering target material according to claim 1, wherein the sputtering target material has a bulk resistivity of 100 mΩ·cm or less at 25° C.

5. The sputtering target material according to claim 1, wherein the sputtering target material contains an In₂O₃ phase and a Zn₃In₂O₆ phase.

6. The sputtering target material according to claim 5, wherein the additive element (X) is contained in both the In₂O₃ phase and the Zn₃In₂O₆ phase.

7. The sputtering target material according to claim 5, wherein the In₂O₃ phase has a crystal grain size of 0.1 µm or more and 3.0 µm or less, and
the Zn₃In₂O₆ phase has a crystal grain size of 0.1 µm or more and 3.9 µm or less.

8. The sputtering target material according to claim 1, wherein a formula (4) is further satisfied:
$$0.970 \leq \text{ln} / \left(\text{ln+X}\right) \leq 0.999 \qquad \text{(4)}$$
.

9. The sputtering target material according to claim 1, wherein the sputtering target material has a standard deviation of Vickers hardness of 50 or less, as measured in accordance with JIS-R-1610:2003.

10. An oxide semiconductor formed by using the sputtering target material according to claim 1,
wherein the oxide semiconductor comprises an oxide including elemental indium (In), elemental zinc (Zn), and an additive element (X),
the additive element (X) is one or more elements selected from tantalum (Ta), strontium (Sr), and niobium (Nb), and
atomic ratios between the elements satisfy formulae (1) to (3):
$$0.4 \leq \left(\text{ln+X}\right) / \left(\text{ln+Zn+X}\right) \leq 0.8 \qquad \text{(1)}$$
$$0.2 \leq \text{Zn} / \left(\text{ln+Zn+X}\right) \leq 0.6 \qquad \text{(2)}$$
$$0.001 \leq \text{X} / \left(\text{ln+Zn+X}\right) \leq 0.015 \qquad \text{(3)}$$
where X represents the sum of ratios of the elements as the additive element.

11. A thin-film transistor comprising an oxide semiconductor,
wherein the oxide semiconductor comprises an oxide including elemental indium (In), elemental zinc (Zn), and an additive element (X),
the additive element (X) is one or more elements selected from tantalum (Ta), strontium (Sr),and niobium (Nb), and
atomic ratios between the elements satisfy formulae (1) to (3):
$$0.4 \leq \left(\text{ln+X}\right) / \left(\text{ln+Zn+X}\right) \leq 0.8 \qquad \text{(1)}$$
$$0.2 \leq \text{Zn} / \left(\text{ln+Zn+X}\right) \leq 0.6 \qquad \text{(2)}$$
$$0.001 \leq \text{X} / \left(\text{ln+Zn+X}\right) \leq 0.015 \qquad \text{(3)}$$
where X represents the sum of ratios of the elements as the additive element, and
the thin-film transistor has a field-effect mobility of 45 cm²/Vs or more.

12. The thin-film transistor according to claim 11, wherein the oxide semiconductor has an amorphous structure.

13. The thin-film transistor according to claim 11, wherein the thin-film transistor has a field-effect mobility of 70 cm²/Vs or more.

14. The thin-film transistor according to claim 11, wherein the thin-film transistor exhibits a threshold voltage of –2 V or more and 3 V or less.
